(19) United States
(12) Patent Application Publication
(10) Pub. No.: US 2020/0185259 A1
(43) Pub. Date: Jun. 11, 2020

(54) SEMICONDUCTOR REACTION DEVICE AND METHOD

(71) Applicant: NATIONAL APPLIED RESEARCH LABORATORIES, Taipei City (TW)

(72) Inventors: Chi-Chung KEI, Hsinchu (TW); Chan-Yuen CHANG, Hsinchu (TW); Chien-Lin CHEN, Hsinchu (TW); Po-Heng LIU, Hsinchu (TW); Yu-Chiao LIN, Hsinchu (TW)

(21) Appl. No.: 16/689,807

(22) Filed: Nov. 20, 2019

(30) Foreign Application Priority Data
Dec. 11, 2018 (TW) 107144628

(51) Int. Cl. H01L 21/687; H01L 21/67; C23C 16/52; C23C 16/455; C23C 16/44

(52) U.S. Cl. CPC H01L 21/68742; H01L 21/67017; H01L 21/67115; C23C 16/4412; C23C 16/52; C23C 16/45544; H01L 21/68764

(57) ABSTRACT

A semiconductor reaction device and a semiconductor reaction method are disclosed. The semiconductor reaction device includes a vacuum chamber, a stage unit, a heating unit, and a first lifting mechanism. The stage unit carries a substrate. When the stage unit drives the substrate to rise, the substrate separates the vacuum chamber to form a reaction space and a bottom space. The heating unit is disposed in the vacuum chamber. The heating unit and the substrate are located on opposite sides of the stage unit. The first lifting mechanism connects with the heating unit so as to move the heating unit, so that the heating unit is movable relative to the stage unit. When the substrate rises to form the reaction space, the distance between the heating unit and the substrate is changed by the first lifting mechanism, thereby changing the temperature of the substrate.

### CROSS REFERENCE TO RELATED APPLICATIONS

This Non-provisional application claims priority under 35 U.S.C. § 119(a) on Patent Application No(s). 107144628 filed in Taiwan, Republic of China on Dec. 11, 2018, the entire contents of which are hereby incorporated by reference.

### BACKGROUND

### Technology Field

The present disclosure relates to a semiconductor reaction device and a semiconductor reaction method. In particular, the present disclosure relates to semiconductor reaction device and a semiconductor reaction method applied to the atomic layer deposition (ALD) process and the atomic layer etching (ALEt) process.

### Description of Related Art

In the semiconductor industry, the integrated circuits (ICs) or photoelectrical components are widely applied in various fields, and the dimension thereof becomes smaller. The atomic layer deposition (ALD) process and the atomic layer etching (ALEt) process play a very important role in the manufacturing of the ICs or photoelectrical components.

In the ALD process, the gas phase precursors are alternately introduced to the substrate inside the heating reactor so as to alternately perform the surface saturation reaction to cause the self-limiting growth, thereby forming a thin film on the substrate. In the ALEt process, the precursors are dissociated in the heating reactor to form the ions reactive with the material of the substrate to be etched, and these ions will chemically react with the exposed portion of the substrate. Afterwards, some of the products in the chemical reaction will be volatilized and removed from the substrate, thereby achieving the dry etching procedure.

### SUMMARY

An objective of this disclosure is to provide a semiconductor reaction device and method that utilize the synchronized temperature-modulation technology to achieve the self-limited reaction, thereby performing the ALD and ALEt processes.

To achieve the above, the present disclosure provides a semiconductor reaction device, which comprises a vacuum chamber, a stage unit, a heating unit and a first lifting mechanism. The stage unit is disposed in the vacuum chamber and carries a substrate. When the stage unit drives the substrate to rise, the substrate separates the vacuum chamber to form a reaction space and a bottom space. The heating unit is disposed in the vacuum chamber, and the heating unit and the substrate are located on opposite sides of the stage unit. The first lifting mechanism is inserted into the vacuum chamber through a bottom portion of the vacuum chamber and connects with the heating unit. The first lifting mechanism is configured for moving the heating unit, so that the heating unit is movable relative to the stage unit. When the substrate rises to form the reaction space, the distance between the heating unit and the substrate is changed by the first lifting mechanism, thereby changing a temperature of the substrate.

In one embodiment, the vacuum chamber has a top portion disposed opposite to the stage unit, and the top portion and the substrate form the reaction space.

In one embodiment, the semiconductor reaction device further comprises a second lifting mechanism inserted into the vacuum chamber through the bottom portion of the vacuum chamber and connecting with the stage unit. The second lifting mechanism drives the stage unit to rise, thereby forming the reaction space and the bottom space.

In one embodiment, the vacuum chamber comprises an inlet channel communicating with the reaction space, and a reaction material enters the reaction space through the inlet channel.

In one embodiment, a non-reaction material enters the reaction space through the inlet channel, and the temperature of the substrate and a temperature of the reaction space are controlled by a flow quantity of the non-reaction material.

In one embodiment, a reaction material is disposed on the substrate.

In one embodiment, the semiconductor reaction device further comprises an exhausting unit, the vacuum chamber comprises an exhausting channel communicating with the reaction space, and an air in the reaction space is exhausted through the exhausting channel and the exhausting unit.

In one embodiment, the heating unit comprises a supporting portion, a heater and a reflector, the first lifting mechanism comprises a lifting shaft connecting with the supporting portion, the supporting portion supports the heater, and the reflector is located between the heater and the supporting portion.

In one embodiment, the heating unit comprises a heater, and an output power of the heater when the substrate and the heater have a second distance therebetween is greater than an output power of the heater when the substrate and the heater have a first distance therebetween.

To achieve the above objective, the present disclosure is to provide a semiconductor reaction method, which is applied to the above-mentioned semiconductor reaction device. The semiconductor reaction method comprises: rising the substrate by the stage unit, so that the substrate separates the vacuum chamber to form the reaction space and the bottom space; and changing a distance between the heating unit and the substrate by the first lifting mechanism so as to change the temperature of the substrate, thereby performing a manufacturing process according to a synchronized temperature-modulation technology.

In one embodiment, the second lifting mechanism drives the stage unit to rise, thereby forming the reaction space and the bottom space.

In one embodiment, the semiconductor reaction method further comprises: providing a reaction material to the reaction space through the inlet channel.

In one embodiment, the semiconductor reaction method further comprises: providing a non-reaction material to the reaction space through the inlet channel, wherein the temperature of the substrate and a temperature of the reaction space are controlled by a flow quantity of the non-reaction material.

In one embodiment, the semiconductor reaction method further comprises: exhausting an air in the reaction space through the exhausting channel and the exhausting unit.

In one embodiment, the semiconductor reaction method further comprises: controlling an output power of the heater when the substrate and the heater have a second distance therebetween to be greater than an output power of the heater when the substrate and the heater have a first distance therebetween.

As mentioned above, in the semiconductor reaction device and method of this disclosure, when the stage unit carries the substrate to rise, the substrate can separate the vacuum chamber to form the reaction space and the bottom space. In addition, the first lifting mechanism is inserted into the vacuum chamber through the bottom portion of the vacuum chamber and connects with the heating unit. The first lifting mechanism can move the heating unit, so that the heating unit is movable relative to the stage unit. When the substrate rises to form the reaction space in the vacuum chamber, the distance between the heating unit and the substrate is changed by the first lifting mechanism, thereby changing a temperature of the substrate. Accordingly, this disclosure can utilize the synchronized temperature-modulation technology to achieve the self-limited reaction of the reaction materials, thereby performing the ALD and ALEt processes.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a schematic diagram showing a semiconductor reaction device according to an embodiment of this disclosure;

FIGS. 2 and 3 are schematic diagrams showing the semiconductor reaction device in different operation statuses according to the embodiment of this disclosure; and

FIG. 4 is a schematic diagram showing a time chart of the synchronized temperature-modulation of the semiconductor reaction device of FIG. 1.

### DETAILED DESCRIPTION OF THE DISCLOSURE

The present disclosure will be apparent from the following detailed description, which proceeds with reference to the accompanying drawings, wherein the same references relate to the same elements.

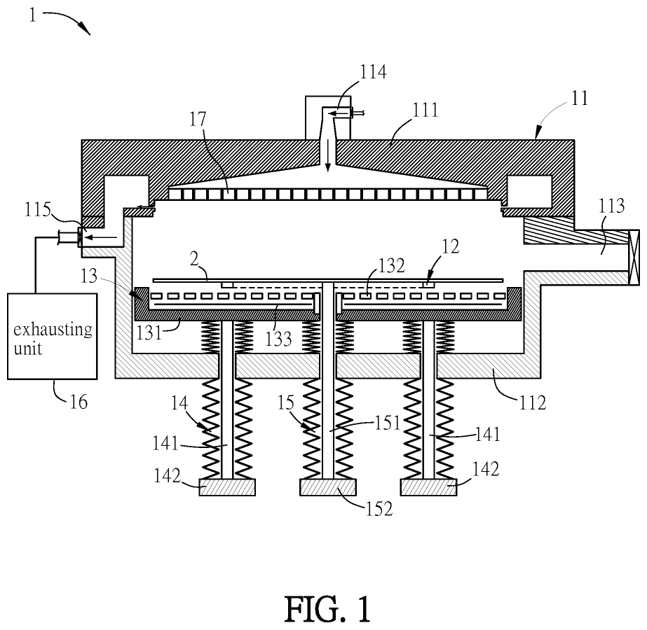

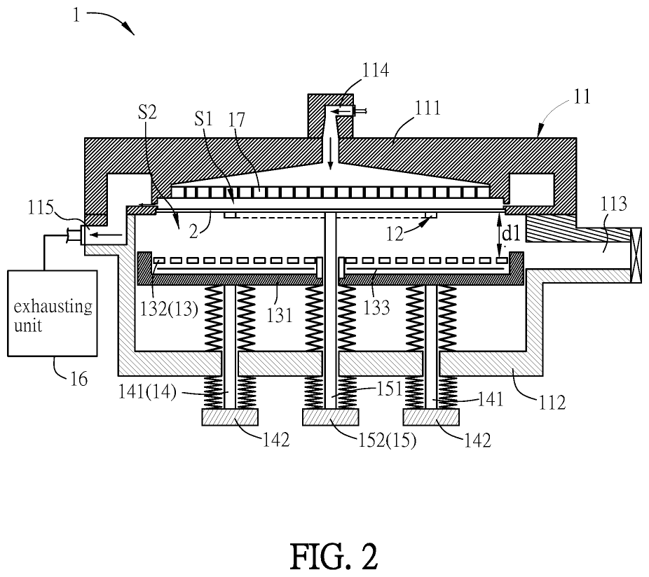

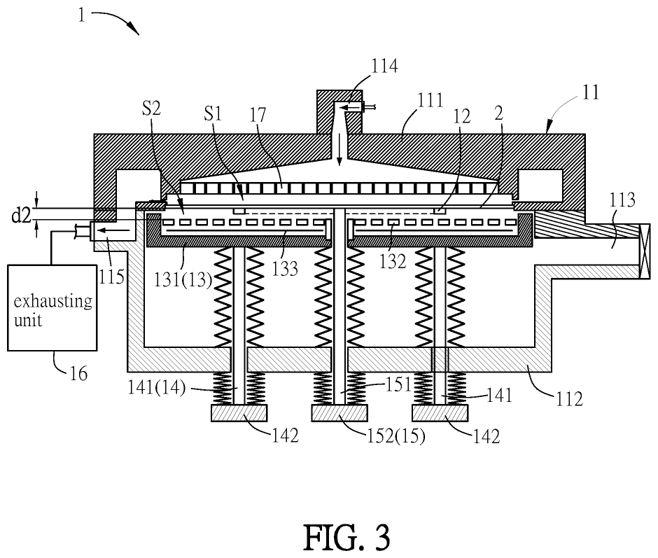

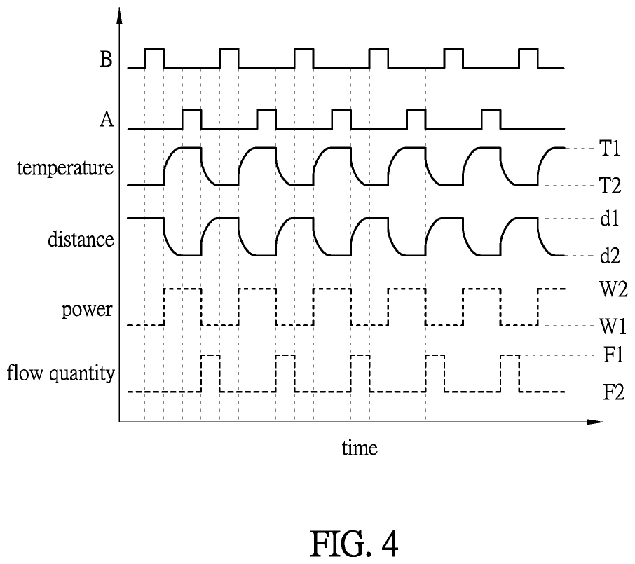

FIG. 1 is a schematic diagram showing a semiconductor reaction device according to an embodiment of this disclosure, FIGS. 2 and 3 are schematic diagrams showing the semiconductor reaction device in different operation statuses according to the embodiment of this disclosure, and FIG. 4 is a schematic diagram showing a time chart of the synchronized temperature-modulation of the semiconductor reaction device of FIG. 1.

As shown in FIGS. 1 to 3, the semiconductor reaction device 1 can be applied to the ALD or ALEt process, and comprises a vacuum chamber 11, a stage unit 12, a heating unit 13, and a first lifting mechanism 14. In addition, the semiconductor reaction device 1 of this embodiment can further comprise a second lifting mechanism 15 and an exhausting unit 16.

The vacuum chamber 11 comprises a top portion 111 and a bottom portion 112, and the top portion 111 and the bottom portion 112 are connected by a side wall (not labeled) to form a reaction chamber. The substrate 2 is disposed in the reaction chamber. The vacuum chamber 11 can be formed by a metal material, and the shape thereof can be roughly a cylinder for providing a space to perform the depositing or etching process of the substrate 2. In addition, the vacuum chamber 11 of this embodiment can further comprise a substrate channel 113, so that the substrate 113 can be put into the vacuum chamber 11 or took out of the vacuum chamber 11 through the substrate channel 113. In practice, a transfer mechanism can be provided to transfer the substrate 2 into the vacuum chamber 11 through the substrate channel 113 and then to place the substrate 2 on the stage unit 12, or the transfer mechanism can be provided to move the substrate 2 out of the vacuum chamber 11 through the substrate channel 113. In some embodiments, the substrate 2 can be a wafer, and it can be made of transparent or nontransparent material, such as a sapphire substrate, a GaAs substrate, or a SiC substrate, and this disclosure is not limited thereto. In other embodiments, the substrate 2 can be formed with one or more layers.

The stage unit 12 is disposed inside the vacuum chamber 11 and is configured to support the substrate 2. The stage unit 12 is located opposite to the top portion 111 of the vacuum chamber 11. In addition, the second lifting mechanism 15 is inserted into the vacuum chamber 11 through the bottom portion 112 of the vacuum chamber 11, and connects with the stage unit 12. In this embodiment, the second lifting mechanism 15 comprises a lifting shaft 151 and a lifting board 152, and the lifting board 152 is connected with the stage unit 12 through the lifting shaft 151. A motor (not shown) is configured for driving the lifting shaft 151 and the lifting board 152 to move, thereby carrying the stage unit 12 to move upwardly or downwardly. When the stage unit 12 carries the substrate 2 to move up, the substrate 2 can separate the vacuum chamber 11 to form a reaction space S1 and a bottom space S2. As shown in FIG. 2, when the lifting shaft 151 of the second lifting mechanism 15 drives the stage unit 12 to move toward the top portion 111 of the vacuum chamber 11, the substrate 2 is also moved upwardly, so that the stage unit 12 and the inner wall of the top portion 111 can form a reaction space S1. Simultaneously, the bottom space S2 can be formed at the other side. Herein, the reaction space S1 is a processing space for depositing or etching of the substrate 2 after the reaction material (e.g. the precursor) enters the vacuum chamber 11. In this embodiment, the second lifting mechanism 15 drives the stage unit 12 to rise, so that the substrate 2 can separate the vacuum chamber 11 to form the reaction space S1 (at the upper side) and the bottom space S2 (at the lower side). Accordingly, when the precursor enters the vacuum chamber 11, it can be restricted in the reaction space S1, thereby preventing the precursor (reaction material) or other gases from entering the bottom space S2 to contaminate the heating unit 13 in the bottom space S2.

The heating unit 13 is disposed in the vacuum chamber 11, and the heating unit 13 and the substrate 2 are located on opposite sides of the stage unit 12. In addition, the first lifting mechanism 14 is disposed next to the second lifting mechanism 15, and the first lifting mechanism 14 is inserted into the vacuum chamber 11 through the bottom portion 112 of the vacuum chamber 11 and connects with the heating unit 13. The first lifting mechanism 14 is configured for moving the heating unit 13, so that the heating unit 13 is movable relative to the stage unit 12. In this embodiment, the heating unit 13 comprises a supporting portion 131, at least one heater 132 (multiple heaters 132 are shown), and a reflector 133. The supporting portion 131 supports the heater 132, and the reflector 133 is located between the heater 132 and the supporting portion 131. When the heater 132 is heating, the temperatures of the substrate 2 and the reaction space S1 can be increased. In addition, the reflector 133 can be, for example but not limited to, a reflective mirror, a reflective sheet, or a reflective film, which can reflect the heat, which is emitted toward the supporting portion 131, to the substrate 2, thereby increasing the thermal efficiency of the heater 132. In some embodiments, in order to increase the heating rate of the substrate 2, the surface of the stage unit 12 can be made of the radiation permeable material, or the stage unit 12 can be formed with a hollow structure, so that the thermal radiation can pass through the stage unit 12 so as to increase the heating rate of the substrate 2.

In this embodiment, the first lifting mechanism 14 comprises a lifting shaft 141 and a lifting board 142, and a motor (not shown) is connected with the lifting shaft 151 through the lifting board 142 and thus further connecting to the supporting portion 131. Accordingly, the motor can drive the lifting shaft 141 and the lifting shaft 151 to move, thereby carrying the heater 13 to move upwardly or downwardly with respect to the stage unit 12 (see FIGS. 2 and 3). In this embodiment, two first lifting mechanisms 14 are configured at two sides of the second lifting mechanism 15, but this disclosure is not limited thereto. In other embodiments, the amount or arrangement of the first lifting mechanisms 14 can be different.

In this embodiment, the top portion 111 of the vacuum chamber 11 is configured with an inlet channel 114 communicating with the reaction space S1, and the reaction material (e.g. the precursor) enters the reaction space S1 through the inlet channel 114. In some embodiments, the reaction material (e.g. a film) can be formed on the substrate 2 depending on the manufacturing process. In addition, the vacuum chamber 11 can further comprise an exhausting channel 115, which is located on the side wall of the vacuum chamber 11 and communicates with the reaction space S1. An air in the reaction space S1 can be exhausted through the exhausting channel 115 and the exhausting unit 16. Moreover, after the chemical reaction in the reaction space S1, the redundant reaction material or side product remained in the reaction space S1 can be exhausted through the exhausting channel 115. In practice, a non-reaction material (e.g. insert gas) can be applied into the reaction space S1 through the inlet channel 114, flow through the upper surface of the substrate 2, and then be exhausted through the exhausting channel 115 and the exhausting unit 16. This configuration can remove the redundant reaction material or side product. Furthermore, the temperature of the substrate 2 and the temperature of the reaction space S1 are controlled by the flow quantity of the non-reaction material, thereby increasing the cooling rate of the substrate 2 and the reaction space S1 (larger flow quantity can cause higher cooling rate).

In addition, the semiconductor reaction device 1 further comprises a gas distribution unit 17 disposed in the vacuum chamber 11 and located in the reaction space S1. The gas distribution unit 17 can evenly distribute the gas entering the reaction space S1 above the substrate 2, which makes the manufacturing process more uniform.

In the deposition process, referring to FIGS. 2 and 4, when the second lifting mechanism 15 drives the stage unit 12 to rise so as to form the reaction space S1 defined by the substrate 2 and the top portion 111 of the vacuum chamber 11, a first distance d1 is formed between the substrate 2 and the heater 132. In this case, the first distance d1 is defined between the lower surface of the substrate 2 and the upper surface of the heater 132 when the stage unit 12 is moved upwardly to form the reaction space S1 between the substrate 2 and the top portion 111 (the heater 132 is not moved in this case). The heater 132 can heat the substrate 2 and the reaction space S1 to a temperature T2. Then, the reaction material (the first reaction material B) enters the reaction space S1 through the inlet channel 114. Under the temperature T2, a chemical reaction of the first reaction material B and the substrate 2 is induced. After the chemical reaction, the redundant reaction material and/or the side product can be exhausted through the exhausting unit 16. In some embodiments, the first distance d1 can be between 20 mm and 100 mm (20 mm<d1<100 mm), and the temperature T2 can be, for example but not limited to, 350° C.

Referring to FIGS. 3 and 4, after forming the reaction space S1, the first lifting mechanism 14 can move the heating unit 13 up to a specific position, so that a second distance d2 is defined between the substrate 2 and the heater 132. Herein, the second distance d2 is smaller than the first distance d1. In this case, the second distance d2 is defined between the lower surface of the substrate 2 and the upper surface of the heater 132 when the stage unit 12 is moved upwardly to form the reaction space S1 between the substrate 2 and the top portion 111 and the heater 132 is moved upwardly to the place underneath the stage unit 12. Thus, the heater 132 is closer to the substrate 2, so that the substrate 2 and the reaction space S1 can be quickly heated to the temperature T1 (T1>T2). Then, another reaction material (the second reaction material A) enters the reaction space S1 through the inlet channel 114. Under the temperature T1, a chemical reaction of the second reaction material A and the substrate 2 is induced. After the chemical reaction, the redundant reaction material and/or the side product can be exhausted through the exhausting unit 16. In some embodiments, the second distance d2 can be between 5 mm and 30 mm (5 mm<d2<30 mm), and the temperature T1 can be, for example but not limited to, 500° C.

In the semiconductor reaction device 1 of this disclosure, the distance between the heating unit 13 and the substrate 2 is changed by the first lifting mechanism 14 based on the reaction material in the reaction space S1, thereby controlling the temperature of the substrate 2 and the reaction space S1. In this disclosure, the synchronized temperature-modulation of the substrate 2 and the reaction material in the reaction space S1 can be achieved by changing the distance between the heating unit 13 (heater 132) and the substrate 2 and heating the substrate 2 and the reaction material by the heating unit 13, thereby performing the self-limiting growth of the reaction material.

For example, in an ALD process (e.g. depositing a GaN layer on the substrate 2), the first reaction material B is a Ga-containing compound such as triethylgallium ((C₂H₅)₃Ga), and the second reaction material A is ammonia (NH₃). After loading the substrate 2 on the stage unit 12, the stage unit 12 is lifted to a reaction position to form the reaction space S1 (see FIG. 2). Next, the materials are supplied to the reaction space S1 through the inlet channel 114 in order (e.g. the order of: the first reaction material B→non-reaction material→the second reaction material A→non-reaction material→the first reaction material B→non-reaction material→the second reaction material A→non-reaction material→ . . . ). Before supplying the first reaction material B (FIG. 2, the first distance d1), the substrate 2 and the reaction space S1 are heated to the temperature T2 (e.g. 350° C.) by the heater 132. Thus, the first reaction material B (triethylgallium) can be attached to the substrate 2 to perform the self-limiting reaction with the substrate 2 so as to form a single layer on the substrate 2. Before supplying the second reaction material A (ammonia), the heating unit 13 is moved upwardly (FIG. 3, the second distance d2), and the substrate 2 and the reaction space S1 are heated to the temperature T1 (e.g. 500° C.) so as to perform the rapid thermal annealing (RTA) process. Thus, the first reaction material B (triethylgallium) can be attached to the substrate 2 after entering the reaction space S1. In this process, the high temperature (T1) can increase the surface diffusion rate and crystallization characteristics of ammonia molecules. Afterwards, the non-reaction material (e.g. for example but not limited to nitrogen or argon) is supplied into the reaction space S1 and then exhausted. At the same time, the heating unit 13 is moved downwardly (FIG. 2, the first distance d1), and the substrate 2 and the reaction space S1 are cooled to the temperature T2. Then, the first reaction material B (triethylgallium) is supplied to the reaction space S1, so that the first reaction material B can be attached to the substrate 2 to perform the self-limiting reaction with the substrate 2 under the temperature T2 so as to form a single layer on the substrate 2. This configuration can maintain the bonding stability of GaN. In order to prevent the first reaction material B (triethylgallium) being cracked at high temperature (T1) and not fully self-limiting growth, it is necessary to cool the reaction space S1 to the temperature T2 before supplying the first reaction material B (triethylgallium). After multiple cycles, the reaction materials attached on the substrate 2 can interact with each other to form the layer of GaN molecules, thereby forming the GaN layer with the desired thickness. In addition, it is also possible to heat at different powers at different distances to change the heating rate or cooling rate of the reaction space S1 and the substrate 2. For example, the output power of the heater 132 is the first power W1 at the first distance d1, and the output power of the heater 132 is the second power W2 at the second distance d2. The second power W2 is greater than the first power W1, so that the reaction space S1 can be rapidly heated and cooled. Furthermore, when the non-reaction material enters the reaction space S1 from the inlet channel 114, the temperature of the reaction space S1 and the substrate 2 can also be controlled by the flow quantity of the non-reaction material. For example, the flow quantity of the non-reaction material can be increased (F>F2) for rapidly cooling the reaction space S1 and the substrate 2.

In addition, in an ALEt process (e.g. etching a Ge layer on the substrate 2 by Cl₂), the first reaction material B is Cl₂, and the second reaction material A is a Ge layer formed on the substrate 2. After loading the substrate 2 on the stage unit 12, the stage unit 12 is lifted to a reaction position to form the reaction space S1 (see FIG. 2). Next, the materials are supplied to the reaction space S1 through the inlet channel 114 in order (e.g. the order of: the first reaction material B→non-reaction material→the first reaction material B→non-reaction material→ . . . ). Before supplying the first reaction material B (FIG. 2, the first distance d1), the substrate 2 and the reaction space S1 are heated to the temperature T2 (the lower temperature) by the heater 132. Thus, the first reaction material B (Cl₂) can be dissociated and attached to the substrate 2 to perform the self-limiting reaction with the substrate 2 so as to form a single layer on the Ge layer. Then, the heating unit 13 is moved upwardly (FIG. 3, the second distance d2), and the substrate 2 and the reaction space S1 are heated to the temperature T1 (T1>T2). Thus, the GeCl specie desorption indicates the etching of the topmost Ge layer. After multiple cycles, the mechanics described above can etch the Ge layer to the desired thickness.

In another embodiment of the ALEt process (e.g. etching a Ge layer on the substrate 2 by oxide such as, for example but not limited to, O₂, H₂O, or H₂O₂), the first reaction material B is an oxide, and the second reaction material A is a Ge layer formed on the substrate 2. As mentioned above, under the lower temperature (T2, the first distance d1), the oxygen ions can perform the self-limiting reaction with the substrate 2 so as to form a single layer on the Ge layer. Under the higher temperature (T1, the second distance D2), the oxygen-Ge species desorption cause the etching of the topmost Ge layer.

With reference to FIGS. 2 and 3, this disclosure also provides a semiconductor reaction method, which is applied to the above-mentioned semiconductor reaction device 1. The semiconductor reaction method can be used in the ALD process or the ALEt process. The specific technology of the semiconductor reaction device 1 can be referred to the above embodiment, so the detailed descriptions thereof will be omitted. The semiconductor reaction method comprises: rising the substrate 2 by the stage unit, so that the substrate 2 separates the vacuum chamber 11 to form the reaction space S1 and the bottom space S2; and changing a distance between the heating unit 13 and the substrate 2 by the first lifting mechanism 14 so as to change the temperature of the substrate 2, thereby achieving the self-limiting reaction according to a synchronized temperature-modulation technology. The other technical features of the semiconductor reaction method can be referred to the above embodiment, so the detailed descriptions thereof will be omitted.

In summary, when the stage unit carries the substrate to rise, the substrate can separate the vacuum chamber to form the reaction space and the bottom space. In addition, the first lifting mechanism is inserted into the vacuum chamber through the bottom portion of the vacuum chamber and connects with the heating unit. The first lifting mechanism can move the heating unit, so that the heating unit is movable relative to the stage unit. When the substrate rises to form the reaction space in the vacuum chamber, the distance between the heating unit and the substrate is changed by the first lifting mechanism, thereby changing a temperature of the substrate. Accordingly, this disclosure can utilize the synchronized temperature-modulation technology to achieve the self-limited reaction of the reaction materials, thereby performing the ALD and ALEt processes.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. A semiconductor reaction device, comprising:
a vacuum chamber;
a stage unit disposed in the vacuum chamber and carrying a substrate, wherein when the stage unit drives the substrate to rise, the substrate separates the vacuum chamber to form a reaction space and a bottom space;
a heating unit disposed in the vacuum chamber, wherein the heating unit and the substrate are located on opposite sides of the stage unit; and
a first lifting mechanism inserted into the vacuum chamber through a bottom portion of the vacuum chamber and connecting with the heating unit, wherein the first lifting mechanism is configured for moving the heating unit, so that the heating unit is movable relative to the stage unit;
wherein when the substrate rises to form the reaction space, the distance between the heating unit and the substrate is changed by the first lifting mechanism, thereby changing a temperature of the substrate.

2. The semiconductor reaction device of claim 1, wherein the vacuum chamber has a top portion disposed opposite to the stage unit, and the top portion and the substrate form the reaction space.

3. The semiconductor reaction device of claim 1, further comprising:
a second lifting mechanism inserted into the vacuum chamber through the bottom portion of the vacuum chamber and connecting with the stage unit, wherein the second lifting mechanism drives the stage unit to rise, thereby forming the reaction space and the bottom space.

4. The semiconductor reaction device of claim 1, wherein the vacuum chamber comprises an inlet channel communicating with the reaction space, and a reaction material enters the reaction space through the inlet channel.

5. The semiconductor reaction device of claim 4, wherein a non-reaction material enters the reaction space through the inlet channel, and the temperature of the substrate and a temperature of the reaction space are controlled by a flow quantity of the non-reaction material.

6. The semiconductor reaction device of claim 1, wherein a reaction material is disposed on the substrate.

7. The semiconductor reaction device of claim 1, further comprising:
an exhausting unit, wherein the vacuum chamber comprises an exhausting channel communicating with the reaction space, and an air in the reaction space is exhausted through the exhausting channel and the exhausting unit.

8. The semiconductor reaction device of claim 1, wherein the heating unit comprises a supporting portion, a heater and a reflector, the first lifting mechanism comprises a lifting shaft connecting with the supporting portion, the supporting portion supports the heater, and the reflector is located between the heater and the supporting portion.

9. The semiconductor reaction device of claim 1, wherein the heating unit comprises a heater, and an output power of the heater when the substrate and the heater have a second distance therebetween is greater than an output power of the heater when the substrate and the heater have a first distance therebetween.

10. A semiconductor reaction method, which is applied to the semiconductor reaction device of claim 1, the semiconductor reaction method comprising:
rising the substrate by the stage unit, so that the substrate separates the vacuum chamber to form the reaction space and the bottom space; and
changing a distance between the heating unit and the substrate by the first lifting mechanism so as to change the temperature of the substrate, thereby performing a manufacturing process according to a synchronized temperature-modulation technology.

11. The semiconductor reaction method of claim 10, wherein the semiconductor reaction device further comprises a second lifting mechanism inserted into the vacuum chamber through the bottom portion of the vacuum chamber and connecting with the stage unit, wherein the second lifting mechanism drives the stage unit to rise, thereby forming the reaction space and the bottom space.

12. The semiconductor reaction method of claim 10, wherein the vacuum chamber comprises an inlet channel communicating with the reaction space, and the semiconductor reaction method further comprises:
providing a reaction material to the reaction space through the inlet channel.

13. The semiconductor reaction method of claim 12, further comprising:
providing a non-reaction material to the reaction space through the inlet channel, wherein the temperature of the substrate and a temperature of the reaction space are controlled by a flow quantity of the non-reaction material.

14. The semiconductor reaction method of claim 10, wherein a reaction material is disposed on the substrate.

15. The semiconductor reaction method of claim 10, wherein the semiconductor reaction device further comprises an exhausting unit, the vacuum chamber comprises an exhausting channel communicating with the reaction space, and the semiconductor reaction method further comprises:
exhausting an air in the reaction space through the exhausting channel and the exhausting unit.

16. The semiconductor reaction method of claim 10, wherein the heating unit comprises a heater, and the semiconductor reaction method further comprises:
controlling an output power of the heater when the substrate and the heater have a second distance therebetween to be greater than an output power of the heater when the substrate and the heater have a first distance therebetween.
